(19) United States
(12) Patent Application Publication
(10) Pub. No.: US 2025/0299762 A1
(43) Pub. Date: Sep. 25, 2025

(54) MONITORING A DEVICE DATA PATH VIA AN EMULATED DATA PATH

(71) Applicant: Micron Technology, Inc., Boise, ID (US)

(72) Inventor: Leon Zlotnik, Camino, CA (US)

(21) Appl. No.: 19/047,192

(22) Filed: Feb. 6, 2025

Related U.S. Application Data
(60) Provisional application No. 63/568,329, filed on Mar. 21, 2024.

(51) Int. Cl. G11C 29/44

(52) U.S. Cl. CPC G11C 29/44

(57) ABSTRACT

The present application relates to monitoring a data path via an emulated data path. In one embodiment, an apparatus can include a device having a data path associated therewith, an error checking component coupled to the device and configured to receive data from the device via the data path, and data path emulation circuitry configured to: toggle between a first data set and a second data set to be provided to the error checking component from an emulated data path to monitor a timing of the data path, and determine whether to provide data to the error checking component from the data path or from the emulated data path based on an operational mode of the device.

### PRIORITY INFORMATION

This application claims the benefit of U.S. Provisional Application No. 63/568,329, filed on Mar. 21, 2024, the contents of which are incorporated herein by reference.

### TECHNICAL FIELD

Embodiments of the disclosure relate generally to electronic devices, and more specifically, relate to monitoring a device data path such as a read data path via an emulated path.

### BACKGROUND

Various types of electronic devices such as digital logic circuits and memory systems may store and process data. A digital logic circuit is an electronic circuit that processes digital signals or binary information, which can take on two possible values (usually represented as 0 and 1). The digital logic circuit can use logic gates to manipulate and transform the digital signals or binary information. Digital logic circuits can be, for example, used in a wide range of electronic devices including computers, calculators, digital clocks, and many other electronic devices that employ digital processing. Digital logic circuits can be designed to perform specific logical operations on digital inputs to generate digital outputs, and, in some instances, can be combined to form more complex circuits to perform more complex operations. A memory device can include one or more memory devices that store data. The memory devices can be, for example, non-volatile memory devices and volatile memory devices. In general, a host system can utilize a memory system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1 illustrates an example electronic system that includes a host, a controller, and a device in accordance with various embodiments of the present disclosure.

FIG. 2 illustrates an example system that includes data path emulation circuitry in accordance with some embodiments of the present disclosure.

FIG. 3 is a flow diagram corresponding to a method for monitoring an emulated path in accordance with some embodiments of the present disclosure.

FIG. 4 is a block diagram of an example computer system in which embodiments of the present disclosure may operate.

### DETAILED DESCRIPTION

Aspects of the present disclosure are directed to a data path monitor (e.g., data path emulation circuitry, error checking component, data integrity component, etc.) to determine a timing and/or data integrity associated with an emulated path (e.g., emulated data path, etc.) that includes delay circuitry to mimic a data path of a device (e.g., a read path of a memory device). Many of the examples herein describe determining the timing of the emulated path, however, the data integrity can also be determined utilizing the emulated path. The emulated path can be an alternate data path that does not interfere with the data path being emulated. The determined timing associated with the emulated path can be compared an expected timing to determine when timing violations associated with the device occur. In this way, the data path emulation circuitry can be utilized to determine aging, voltage drops, clock frequency swings, among other properties of the device utilizing properties (e.g., timing, data integrity, etc.) associated with the emulated path. In some embodiments, the data path emulation circuitry can be utilized to trigger Functional Safety (FUSA) alerts related to voltage, circuit failure, and/or security threats (e.g., thermal attacks, power supply attacks, physical tampering, etc.). Although FUSA alerts are utilized as a specific example, other types of system alerts are also possible.

In some embodiments, the device path is a memory read data path. Although a memory read data path is used as a specific example, other device paths such as, but not limited to: memory write data paths, cache memory data paths, direct memory access (DMA) paths, and/or input/output (I/O) data paths. The memory read data path can be critical to a flow of data between a processor and memory units such as random access memory (RAM). The device path can include a plurality of functions. For example, the memory read data path can include a plurality of functions such as, but not limited to: address generation, address transmission, memory controller activation, data retrieval, data transmission, and/or data processing. In some embodiments, the memory read data path can include both the memory access time and logic propagation.

In previous embodiments, it can be difficult to determine a timing for an entire bus (e.g., data bus, etc.) associated with the memory device. For example, previous embodiments can utilize a quantity of representative bits from the memory data to check (e.g., monitor) the timing of the memory device. However, the quantity of representative bits can be relatively small and not be representative of the entire bus. As used herein, a bus or data bus can refer to a device or system that transfers data between components of a computing device or between computing devices.

In order to address these and other deficiencies of current approaches, embodiments of the present disclosure allow an emulated path to represent a data read path or similar data path of a device and determine the timing of the emulated path to determine timing issues associated with the entire bus of the device. In some embodiments, the data path emulation circuitry can be utilized to determine a timing of an emulated path that includes delay circuitry to mimic a read data path of a memory device.

The data path emulation circuitry can be utilized to determine the timing of the emulated path when a memory device is not actively performing a read operation (e.g., non-read operational mode, etc.). For example, the data path emulation circuitry can determine the timing of the emulated path when the memory device is performing a write operation and/or when the memory device is in a non-read operational mode. As described herein, the device can be in a non-read operational mode and utilize the emulated data path to determine a timing of the emulated path. In some embodiments, a non-read operational mode is a mode of operation when the device is not performing a read operation. In other embodiment, the non-read operational mode refers to a mode of operation when the device is not utilizing the data bus to transmit data. That is, the device can be in any number of operation modes other than a read mode (e.g., actively reading, etc.) when utilizing the emulated data path to determine if there are timing violations associated with the device. When the memory device is not actively reading, the error checking component can receive toggled data that is provided to a multiplexor via the emulated path. In this way, along with the delay circuits of the emulated path, the error checking component can determine the timing of the emulated path and compare the timing to an expected timing to determine if the device is experiencing a violation (e.g., timing violation, etc.).

Although some non-limiting examples herein are generally described in terms of applicability to memory systems and/or to memory devices, embodiments are not so limited, and aspects of the present disclosure can be applied as well to a system-on-a-chip, computing sub-system, data collection and processing, storage, networking, communication, power, artificial intelligence, control, telemetry, sensing and monitoring, digital entertainment and other types of systems/sub-systems and/or devices. Accordingly, aspects of the present disclosure can be applied to these components in order to monitor a device path, as described herein. As used herein, a device path can be a path along which the device receives data and/or provides data. For example, the device path can include an input path and/or an output path.

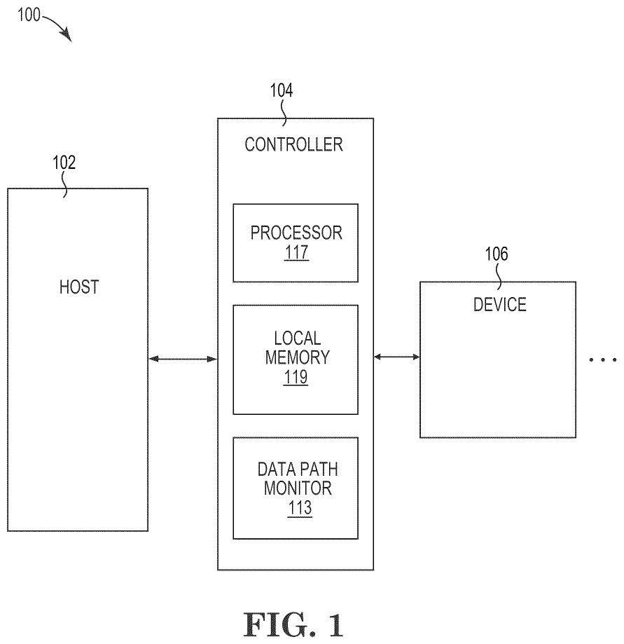

FIG. 1 illustrates an example electronic system 100 that includes a host 102, a controller 104, and a device 106 in accordance with various embodiments of the present disclosure.

The electronic system 100 can be, or can be part of, for example, a desktop computer, laptop computer, televisions, home theater system, gaming console, digital camera, network router and/or switch, printer, scanner, medical device, GPS navigation device, home device (e.g., thermostat, doorbell camera, security camera, smart lock, etc.), wearable device, industrial control system (e.g., automated industrial and/or control device) mobile computing device, a vehicle (e.g., airplane, drone, train, automobile, or other conveyance), Internet of Things (IoT) enabled device, embedded computer (e.g., one included in a vehicle, industrial equipment, or a networked commercial device), system-on-chip (SoC), chipset (e.g., a collection of integrated circuits), tile, Field-Programmable Gate Array (FPGA) structure (e.g., segmented FPGA structure), or other such device.

The electronic system 100 can be, or can include, a computing fabric. As used herein, the term “computing fabric” generally refers to a conveying, multiplexing, network, computing, or communication topology in which components pass data to each other through interconnecting switches, hubs, routers, multiplexers, buses, transmission lines and rings, cables, optical couplers and fibers, electromagnetic devices, or various other means. For example, a “computing fabric” can include various components (e.g., interconnects, crossbars, networks on chip, token rings, etc.) within a computing, memory, data storage and/or processing, network and/or telecommunication, artificial intelligence, control and/or telemetry, digital entertainment and/or other system, that facilitates in-chip and/or inter-chip communication.

The electronic system 100 includes a host 102. The host 102 can include a processor chipset and a software stack executed by the processor chipset. For example, the host 102 can be, or can include, a central processing unit (CPU) or a CPU complex that can be configured to execute an operating system.

The host 102 can be coupled to the controller 104 via a physical and/or logical host interface that operates based on various communication protocols and to provide control, address, data, and other signals to the controller 104 (e.g., to further cause the controller 104 to control the device 106). Examples of the interface between the host 102 and the controller 104 can include, but not limited to, a bus interface (e.g., a serial advanced technology attachment (SATA) interface, a Serial Attached SCSI (SAS) interface, a Serial Attached SCSI (SAS) interface, a Small Computer System Interface (SCSI), a peripheral component interconnect express (PCIe) interface, ISA, etc.), a memory interface (e.g., a double data rate (DDR) interface, a dual in-line memory module (DIMM) interface, an Open NAND Flash Interface (ONFI) interface, an NVM Express (NVMe) interface), a Fibre Channel, an UART interface, an I2C interface, a Serial Peripheral Interface (SPI), an Universal Serial Bus (USB) interface, an ethernet interface, a general-purpose input/output (GIPO) interface, a custom interface, etc.

The controller 104 is communicatively coupled to one or more electronic devices 106 such that signaling can be exchanged therebetween. Non-limiting examples of the devices 106 can include microcontrollers, microprocessors, digital logic circuits, analog circuits, light emitting diodes (LEDs), displays, sensors, motors, actuators, audio amplifiers, radio frequency (RF) circuits, test and measurement instruments (e.g., oscilloscopes, multimeters, etc.), automotive electronics, medical devices, telecommunication equipment, memory devices (e.g., volatile and/or non-volatile memory devices), graphics processing units, processors/co-processors, logic blocks, intellectual property (IP) cores, etc. As used herein, a “core” or “IP core” generally refers to one or more blocks of data and/or logic that form constituent components of an application-specific integrated circuit or field-programmable gate array. The circuit portion areas can be designed, built, and/or otherwise configured to perform specific tasks and/or functions within the systems described herein.

As shown in FIG. 1, the controller 104 can include a processing device (e.g., processor 117) that can execute instructions stored in a local memory 119 to perform various operations described herein. The controller 104 can include various special purpose circuitry in the form of an ASIC, FPGA, state machine, and/or other logic circuitry that can perform operations described herein. As an example, the controller 104 can be a memory controller.

In various embodiments, one or more constituent components (e.g., host 102, controller 104, device 106, etc.) of system 100 can be part of a SoC. In one example, a device 106 itself can correspond to an SoC, while the host 102 and the controller 104 are considered “external” to the SoC. In another example, the host 102 or the controller 104, or both, can be considered as a part of an SoC along with the device 106 being internal or external to the SoC.

As shown in FIG. 1, the controller 104 can include data path monitor 113 (e.g., error checking component and/or data path emulation circuitry, etc.). The data path monitor 113 can be resident on the controller 104. In other embodiments, the data path monitor 113 or a portion of the data path monitor 113 by not be resident on the controller 104. For example, a portion of the emulated path associated with the data path monitor 113 may not be resident on the controller 104. As used herein, the term “resident on” refers to something that is physically located on a particular component. For example, the data path monitor 113 being “resident on” the controller 104, for example, refers to a condition in which the hardware circuitry that comprises the data path monitor 113 is physically located on the controller 104. The term “resident on” may be used interchangeably with other terms such as “deployed on” or “located on,” herein. In some embodiments, the data path monitor 113 is part of the host 102, an application, or an operating system. Although not shown in FIG. 1 so as to not obfuscate the drawings, the data path monitor 113 can include various circuitry to facilitate aspects of the disclosure described herein. For example, the data path monitor 113 can include various circuitry to facilitate determining a timing of an emulated data path to identify potential timing violations of a memory device.

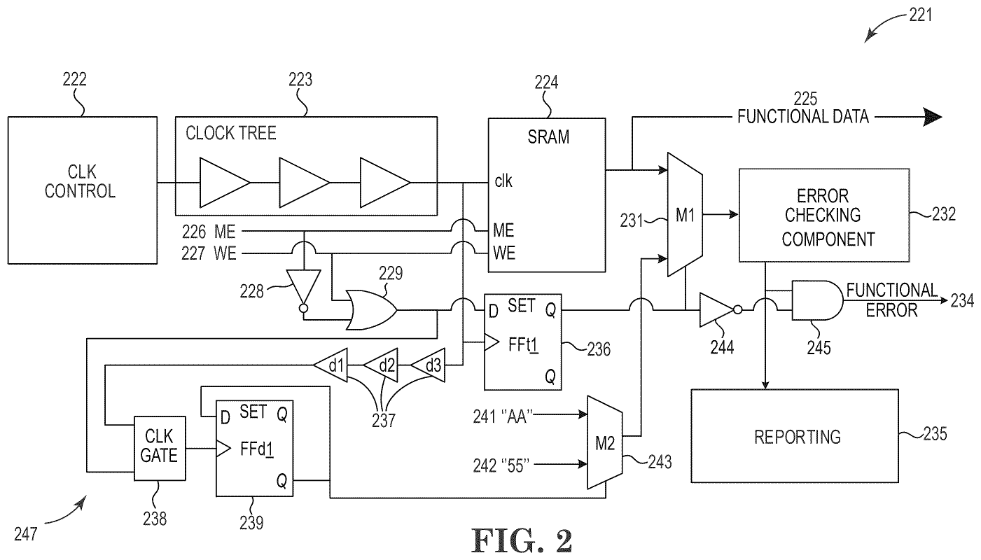

FIG. 2 illustrates an example system 221 that includes data path emulation circuitry 247 in accordance with some embodiments of the present disclosure. The system 221 can be, for example, a system that can include a device 224. The device 224 can be, for example, a memory device. In some embodiments, the device 224 can have a data path (e.g., a read data path and/or a write data path) associated therewith. The system 221 can also include a clock controller 222, a clock tree 223, error checking component 232, and/or reporting circuitry 235. As described further herein, the system 221 can utilize an emulated path that includes one or more flip-flop circuits, one or more multiplexors, one or more delay circuits, and one or more gates to mimic a timing of the data path of the device 224. In some embodiments, the data path is a read data path and the device 224 is a memory device.

Although the device 224 is shown as static random-access memory (SRAM), the device 224 can be implemented as other types of memory or other types of devices. For example, the device 224 can be a system-on-a-chip, computing sub-system, a data collection and processing device, a networking device, a communication device, power device, an accelerator (e.g., artificial intelligence accelerator, etc.), a control device, a telemetry device, a sensing and monitoring device, a digital entertainment device, an interface, and/or a fabric, among other types of devices.

As used herein, the clock controller 222 can include circuitry to generate or provide clocking signals (e.g., clock pulses, etc.) that can be utilized to coordinate operations of the system 221. For example, the clocking signals can be utilized to maintain an integrity of data transfer between a processor and the device 224 or other type of memory device. As described herein, the clocking signals can be vital to data transfer. Even a slight timing error can result in faults or errors of the system 221. The system 221 can include a clock tree 223 that can be utilized to maintain synchronized operation of various components of the system 221.

In some embodiments, the clock tree 223 can include a plurality of components to perform various functions. For example, the clock tree 223 can include buffers to strengthen a clock signal received by the clock controller 222 to create different frequencies for different parts of the system 221. In some embodiments, the clock tree 223 can include other components such as, but not limited to: inverters, clock gates, muxes, level shifters, and/or other components to strengthen a clock signal.

The clock tree 223 can distribute clocking signals to the device 224. As described herein, the clocking signals can be utilized by the device 224 to perform a plurality of different operations. For example, the clocking signals can be used to synchronize memory read operations, memory write operations, among other types of operations. In some embodiments, the device 224 can provide signals to a first multiplexor 231 and/or provide functional data 225 to other devices or systems.

In some embodiments, the clock tree 223 can provide clocking signals to a first flip-flop circuit 236. The first flip-flop circuit 236 can be a device that is able to change states in response to an input signal. In some embodiments, the first flip-flop circuit 236 can be coupled to a first multiplexor 231 and a NOT gate 244. As described further herein, the first flip-flop circuit 236 can receive a signal that identifies a state of the device 224. In some embodiments, the signal from the first flip-flop circuit 236 can be provided to indicate whether data from the device 224 will be provided to the error checking component 232 or whether data from the emulated path will be provided to the error checking component 232.

As described further herein, the emulated path can include a plurality of components to mimic a timing of a data path of the device 224 or provide an expected timing. For example, the emulated path can include a plurality of delay circuits 237, a clock gate 238, and/or a second multiplexor 243. In some embodiments, the system 221 can include data path emulation circuitry 247 that can include portions of the emulated path including, but not limited to: the NOT gate 228, the OR gate 229, the first flip-flop circuit 236, the plurality of delay circuits 237, the clock gate 238, the second flip-flop circuit 239, the second multiplexor 243, the first multiplexor 231, and/or the error checking component 232. In this way, the data path emulation circuitry 247 can be utilized to determine a timing of the emulated path of the system 221 (e.g., when the device 224 is not actively performing a read operation).

In some embodiments, the error checking component 232 can be coupled to the device 224 to receive data from the device 224 via the data path associated with the device 224. For example, the error checking component 232 can receive data from the device 224 through the first multiplexor 231 when the device 224 is performing a read operation. In these embodiments, the error checking component 232 can determine if there were errors associated with the data. For example, the error checking component 232 can determine if there were timing errors or data integrity errors (e.g., data accuracy errors, etc.) associated with data received from the device 224. As an example, the error checking component 232 can be a single error correction double error detection (SECDED) decoder, although embodiments are not so limited.

In some embodiments, the system 221 can utilize the data path emulation circuitry 247 to determine properties of the emulated data path. As described herein, the system 221 can utilize the data path emulation circuitry 247 to determine a timing of an emulated data path of the device 224 during particular operational modes. For example, the system 221 can determine whether the device 224 is in one of a read mode or a non-read mode (e.g., write mode, idle mode, etc.).

As used herein, a read mode of the device 224 refers to a mode in which the device 224 is enabled/active and is performing a read operation, a write mode of the device 224 refers to a mode in which the device 224 is enabled/active and is performing a write operation, and an idle mode of the device 224 refers to a mode in which the device 224 is disabled/inactive such that it is not able to perform a write or read operation. In some embodiments, the disabled/inactive mode can be referred to as an idle mode, which can include a power saving mode or other mode in which the device is not actively performing read or write operations. Although specific operation modes are described, many other modes can also be utilized without departing from the disclosure.

In some embodiments, the system 221 is configured to provide data from the data path to the error checking component 232 when the device 224 is in the read mode and provide data from the emulated data path when the device 224 is in the non-read mode. In these embodiments, the system 221 can utilize the NOT gate 228 and/or OR gate 229 to determine the operational mode of the device 224.

In some embodiments, the non-read operation can refer to an operational mode of the device 224 where data is not being transferred through a data bus associated with the device 224. For example, in some embodiments, the system 221 can be configured to determine whether to provide data to the error checking component 232 from the data path of the device 224 or from the emulated path based on an operational mode of a data bus associated with the device 224. For example, the operational mode of the data bus can refer to a data transfer operational state, a non-transfer operational state, and/or a plurality of other operational states. In these examples, the data transfer operational state can refer to a time when the data bus is being utilized to transfer data. In these examples, the non-transfer operational state can be a state when the data bus is not transferring data. In this way, the system 221 can provide toggled data from the emulated path when the data bus is in the non-transfer operational state and provide data from the device 224 when the data bus is in a data transfer operational state.

In some embodiments, the system 221 includes a memory enable (ME) signal 226 and a write enable (WE) signal 227. Traditionally the ME signal 226 is used to enable the device 224 or disable the device 224. In some embodiments, the ME signal 226 is high (e.g., signal of “1”, etc.) to activate the device 224 and the ME signal 226 is low (e.g., signal of “0”, etc.) to deactivate the device 224. In a similar way, the WE signal 227 can be utilized to indicate whether the device 224 is in a read mode or a write mode. In some embodiments, the WE signal 227 is high (e.g., signal of “1”, etc.) to perform a write operation and the WE signal 227 is low (e.g., signal of “0”, etc.) to perform a read operation.

In some embodiments, the system 221 can include a NOT gate 228. As used herein, a NOT gate can be a logical gate. In some embodiments, the NOT gate 228 can perform a logical negation or logical inversion. For example, an input of a low signal (e.g., signal of “0”) can be inverted to a high signal (e.g., signal of “1”). In some embodiments, the ME signal 226 can be provided to an input of the NOT gate 228. In this way, the ME signal 226 can be inverted by the NOT gate 228. Thus, in these embodiments, the NOT gate 228 can convert an active high signal from the ME signal 226 and invert it to a low signal. Similarly, the NOT gate 228 can convert a deactivate low signal from the ME signal 226 and invert it to a high signal. The output signal from the NOT gate 228 can be provided to an OR gate 229. As used herein, an OR gate 229 refers to a logical gate that can combine multiple binary conditions or signals. In some embodiments, the OR gate 229 can be utilized to determine a logical “or” where if one of the inputs is “true” then the output of the OR gate 229 will be true. For example, if one of the signals received by the OR gate 229 is a high signal then the output of the OR gate 229 will be a high signal.

In this example, a first input of the OR gate 229 receives from the output of the NOT gate 228 and a second input of the OR gate 229 receives the WE signal 227. In some embodiments, when either the NOT gate 228 or the WE signal 227 provide a high signal to the OR gate 229, the OR gate 229 will provide a high signal as an output. For example, the WE signal 227 can be a high signal (e.g., signal of “1”) provided to the OR gate 229 and the OR gate 229 can provide a high signal output. In a similar way, the NOT gate 228 can provide a high signal to the OR gate 229 when the ME signal 226 is a low signal. In this example, the OR gate 229 can provide a high signal output in response to receiving the high signal from the OR gate 229. Thus, in some embodiments, the OR gate 229 can provide a low signal when both the WE signal 227 and the NOT gate 228 are low signals. In this way, the OR gate 229 can be utilized to provide a high signal when either the device 224 is disabled by the ME signal 226 and/or when the device 224 is enabled for a write operation by the WE signal 227.

In some embodiments, the first flip-flop circuit 236 can be utilized to mimic a latency (e.g., memory read latency). In this way, the first flip-flop circuit 236 can allow the system 221 to implement a particular latency when switching from the data path of the device 224 to the emulated path. In some embodiments, additional flip-flop circuits can be utilized in addition to the first flip-flop circuit 236. For example, the quantity of flip-flop circuits can depend on time or clock count of a latency of the system 221. For example, the first flip-flop circuit 236 can provide a one clock latency. In this example, an additional flip-flop circuit can be added to the system 221 to provide a two-clock latency.

As used herein, a clock gate 238 can refer to an electrical device or circuit that can control distribution of clock signals. For example, the clock gate 238 can be utilized to either provide clocking signals to a second flip-flop circuit 239 or prevent clocking signals from being provided to the second flip-flop circuit 239. In some embodiments, the clock gate 238 can be utilized to conserve electricity and/or performance of the system 221 by deactivating signals that are provided to the second flip-flop circuit 239.

In some embodiments, the second flip-flop circuit 239 can be utilized to provide selection signals to the second multiplexor (MUX) 243. In some examples, the second flip-flop circuit 239 can perform a toggling to alternate the selection signals provided to the second multiplexor 243. In these embodiments, the second flip-flop circuit 239 can provide a first selection signal to the second multiplexor 243 such that the second multiplexor 243 provides a first value from a first data set. For example, the second multiplexor 243 can receive a first selection signal from the second flip-flop circuit 239 and the second multiplexor 243 can provide a first hex value “AA” 241 to the first multiplexor 231. In this example, the second multiplexor 243 can receive a second selection signal from the second flip-flop circuit 239 and the second multiplexor 243 can provide a second hex value “55” 242 to the first multiplexor 231. In this way, the second flip-flop circuit 239 and second multiplexor 243 can provide the toggling data set from the emulated path to the error checking component 232 to monitor a timing of the emulated path. Although a first data set and a second data set are described herein, additional data sets can be toggled in a similar way without departing from the present disclosure. In addition, although a first hex value “AA” 241 and a second hex value “55” are utilized as specific examples, other hex values or data sets can be utilized.

The error checking component 232 can determine whether a received signal is correct (e.g., “AA” 241 signal or “55” 242 signal) to determine a timing of the emulated path. For example, the error checking component 232 can identify a data signal that is expected to be received and determine if the data signal is the correct signal. In some embodiments, the data signal can be utilized to determine a timing of the emulated path that can be utilized to determine a functionality of the data path of the device 224. As described herein, the timing of the emulated path can refer to a quantity of a data timing of the emulated path. For example, the timing of the emulated path can be a quantity of time between when the clocking signal is generated by the clock controller 222 and when the data signal is received at the error checking component 232. In these embodiments, the error checking component 232 can determine the timing based on a determined time of a received data signal.

As described herein, the error checking component 232 can receive output signals from the first multiplexor 231. In some embodiments, the first multiplexor 231 can receive signals from the second multiplexor 243 or the device 224. In some embodiments, the signals from the device 224 received at the first multiplexor 231 can be passed through to the error checking component 232 to determine a current timing of signals that are processed by the device 224. In this way, the error checking component 232 can determine the current timing of the data signals that are processed by the device 224 in a similar way that the error checking component 232 can determine a current timing of the data signals that are processed by the emulated path. As described herein, the emulated path can be configured to have the same or similar timing as the data path of the device 224. However, in other embodiments, the emulated path can be configured to have a different timing than the data path of the device 224. For example, the emulated path can be configured to have a timing that is a ratio of the timing of the device 224. In this way, the error checking component 232 can determine when the timing of the emulated path is outside of a threshold timing and utilize this determination to determine that there may be a corresponding error associated with the data path of the device 224.

In some embodiments, the functional data 225 can be provided to an exterior system or device. As used herein, the functional data 225 can be data that is read from the device 224 through a read operation. In this way, the functional data 225 can be read data that is provided to a host device or host system in response to a read operation from the host device or host system.

In some embodiments, the error checking component 232 can provide signals to reporting circuitry 235. In some embodiments, the reporting circuitry 235 can generate a report associated with the device 224 and/or the emulated path. In some examples, the reporting circuitry 235 can generate a report related to secure operation, error telemetry, dynamic voltage management system (DVFS), or other properties associated with the system 221. For example, the reporting circuitry 235 can be FUSA reporting circuitry that is able to generate notifications related to FUSA reports. Although FUSA reports are described herein, the present disclosure is not so limited. For example, the reporting circuitry 235 can generate a plurality of different reports that can describe a property of the device 224 and/or emulated path. In some embodiments, the error checking component 232 and/or the reporting circuitry 235 can determine a failure based on the difference in timing between the emulated path and a threshold.

As described herein, a timing violation of the device 224 or a timing violation of the emulated path can be caused by a number of different issues associated with the system 221. For example, the timing of the emulated path can be below a threshold timing or be slower than an expected timing when there is circuitry degradation or aging. In this way, there can be possible circuitry degradation associated with the device 224. In these embodiments, the reporting circuitry 235 can be utilized to generate a plurality of different failure reports (e.g., FUSA reports, security reports, power management reports, etc.) based on the timing at a particular time or a timing change over a period of time.

Memories marked as FUSA are critical for the safe operation of the system. If these memories and/or paths fail or are corrupted, the system is designed to recognize failure and take appropriate action to either correct the error or enter a safe state to prevent further issues. FUSA can be integral to ensuring the reliability and safety of systems where failure can lead to significant consequences to the memory device. A device path, such as a memory read data path can be a timing critical path. That is, particular device paths can result in critical failures when there is a failure or corruption of the particular device paths. The device path can become compromised due to security threats, aging, circuit failures, or other issues. A compromised device path can result in timing violations, which can compromise a system that is utilizing the memory device. As described herein, FUSA reports are a specific example of reports that can be generated by the system 221. For example, other types of reports such as, but not limited to, power management reports, security reports, or other system reports can be generated.

In some embodiments, the system 221 can include an AND gate 245. The AND gate 245 can include a first input from the error checking component 232 and a second input from a NOT gate 244. As described herein, the NOT gate 244 can perform a logical negation or logical inversion. For example, an input of a low signal (e.g., signal of “0”) can be inverted to a high signal (e.g., signal of “1”). The NOT gate 244 can receive a signal from the first flip-flop circuit 236 that can indicate when a signal to the device 224 includes one of a ME signal 226 that is a low signal or a WE signal 227 that is a high signal that is provided to the OR gate 229. In this way, the signal to the NOT gate 244 can be an indication of whether the data provided to the first multiplexor 231 is functional data 225 or testing data from the emulated path through the second multiplexor 243. In this way, the AND gate 245 can receive a low signal from the NOT gate 244 when the device 224 is not performing a read operation and receive a high signal from the NOT gate 244 when the device 224 is performing a read operation. This can allow the AND gate 245 to determine that there is a functional error 234 to functional data 225 in contrast to a timing error associated with the emulated path through the second multiplexor 243. As described herein, the first flip-flop circuit 236 can also be utilized to account for a data path latency.

In specific embodiments, the system 221 can include an apparatus. As described herein, an apparatus can include a first flip-flop circuit to receive an indication signal that a memory device is in a particular state. In some embodiments, the first flip-flop circuit (e.g., first flip-flop circuit 236, etc.) can be configured to send a selection signal to a multiplexor (e.g., first multiplexor 231, etc.) when the memory device (e.g., device 224, etc.) is in the particular state. As described herein, the first flip-flop circuit 236 can be utilized to switch the multiplexor based on whether the device 224 is performing a read operation or not.

As described herein, the system 221 and/or apparatus can include a plurality of delay circuits 237 coupled to the emulated path to provide a timing that mimics a timing of a memory read operation of the memory device or device 224. In some embodiments, the device 224 can be designed to perform a particular operation (e.g., read operation, etc.) within particular timing parameters. In this way, the plurality of delay circuits 237 can be designed to mimic the particular timing parameters of the device 224 when performing the particular operation. That is, the quantity of time it takes the device 224 to perform a read operation can be the same or similar time it takes the signal to pass through the emulated path that includes the plurality of delay circuits 237. In other embodiments, the delay circuits 237 can be utilized to mimic an operation of a particular timing that may be different than the read operation of the device 224.

In some embodiments, the apparatus can include a second flip-flop circuit 239 to receive a clocking signal in response to the memory device being in the particular state. As described herein, the second flip-flop circuit 239 can receive the clocking signals from the clock gate 238 when the clock gate 238 determines the device 224 is not performing a read operation.

In some embodiments, the apparatus can include a multiplexor (e.g., second multiplexor 243, etc.) to create a designated data signal (e.g., “AA” 241 and/or “55” 242, etc.) being controlled by the second flip-flop circuit 239 in response to receiving clocking signals from the clock gate 238. As described herein, the designated data signal can be a toggling data signal that can be utilized to identify a timing of the emulated path.

In some embodiments, the system 221 can be configured to generate a report when the timing of the emulated path is outside the threshold timing. As described herein, the error checking component 232 can utilize a threshold timing associated with the device 224. The threshold timing can be a range of timing values that are within an acceptable timing range for the particular device. In this way, the error checking component 232 can determine when a timing violation is outside a threshold value and provide the timing violation to the reporting circuitry 235. The system 221 can also be configured to determine the timing of the emulated path based on the designated data signal received. As described herein, the designated data can be toggling data that is provided by the second multiplexor 243 in order to allow the error checking component 232 to identify the sequentially received data signals.

In a different specific embodiment, the system 221 can include a first flip-flop circuit 236 to receive an indication signal that a memory device (e.g., device 224, etc.) is in a write enable state and a second flip-flop circuit 239 to receive a plurality of clocking signals from an emulated path in response to the memory device being in the write enable state. The plurality of clocking signals can be utilized by the second flip-flop circuit 239 to provide selection signals to a second multiplexor 243 for providing toggled data to the first multiplexor 231. As described herein, the designated data can be toggled between a first static data value (e.g., “AA” 241, etc.) and a second static data value (e.g., “55” 242, etc.).

In this specific embodiment, the first flip-flop circuit 236 can be configured to send a signal to the first multiplexor 231 to switch between providing functional data 225 from the device 224 to providing the designated data signals from the emulated path to the checking component (e.g., error checking component 232). In this specific embodiment, the system 221 can include error checking component 232 configured to receive the corresponding designated data signals from the first multiplexor 231 to determine a timing of the emulated path and compare the timing of the emulated path to a threshold timing associated with the memory device (e.g., device 224, etc.). As described herein, threshold timing can be based on an expecting timing of the emulated path based on the configuration of the delay circuits 237 and/or other components of the data path emulation circuitry 247.

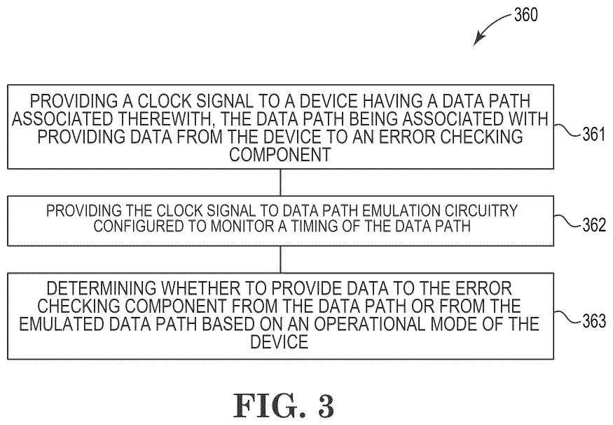

FIG. 3 is a flow diagram corresponding to a method 360 for monitoring an emulated path in accordance with some embodiments of the present disclosure. The method 360 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 360 is performed by the data path monitor 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

The method 360 can be executed at step 361 to provide a clock signal to a device having a data path associated therewith, the data path being associated with providing data from the device to an error checking component. In some embodiments, the method 360 can utilize a clock controller (e.g., clock controller 222 as referenced in FIG. 2, etc.) that can include circuitry to generate or provide clocking signals (e.g., clock pulses, clock signals, etc.) that can be utilized to coordinate operations of the device. For example, the clocking signals can be utilized to maintain an integrity of data transfer between a processor and the device. As described herein, the clocking signals can be vital to data transfer. Even a slight timing error can result in faults or errors of the device.

The method 360 can be executed at step 362 to provide the clock signal to data path emulation circuitry configured to monitor a timing of the data path. In some embodiments, providing the clock signal to the data path emulation circuitry includes providing the clock signal to an emulated path, toggling between at least a first data set and a second data set, and/or providing the toggled data to the error checking component based on the clock signal.

As used herein, the emulated path can be an alternate path or electrical path that is not provided to a device with the data path. In this way, the emulated path can include a plurality of delay circuits (e.g., delay circuits 237 as referenced in FIG. 2, etc.) to mimic the timing of the device performing a read operation or other type of operation. The signal can be a clocking signal provided by a clock controller and/or clock tree.

In some embodiments, the method 360 can be executed to prevent the clock signal from being provided to the emulated path when the operation mode of the device is a read operational mode. As described herein, the data path emulation circuitry can determine when the device is in a read operational mode and provide functional data to the error correction circuitry instead of toggled data from the emulated path. As described herein, the checking component (e.g., error checking component 232 as illustrated in FIG. 2, etc.) can be activated by a signal to a multiplexor (e.g., first multiplexor 231 as illustrated in FIG. 2, etc.). In some embodiments, activating the checking component can refer to altering the checking component from monitoring functional data provided through the memory device to monitoring data provided through the emulated path (e.g., through the second multiplexor 243 as referenced in FIG. 2, etc.). In this way, the checking component can be notified when there is functional data being provided through the memory device and when there is non-functional data being provided through the emulated path. By monitoring both the functional data and non-functional data, the checking component can determine degradation of timing over a period time for the memory device and/or the emulated path. In a similar way, the checking component can be utilized to check or monitor the functional data as well as monitor the timing of the signals through the emulated path.

The method 360 can be executed at step 363 to determine whether to provide data to the error checking component from the data path or from the emulated path based on an operational mode of the device. As described herein, the method 360 can include providing the error checking component with data from the data path of the device when the device is in a read mode and providing the error checking component with toggled data from the emulated path when the device is in a non-read mode.

The method 360 can be executed to determine when the timing of the signal is outside a threshold. As described herein, when the timing of the signal provided through the emulated path is outside a threshold timing, the checking component can generate a notification that there is a timing failure associated with the memory device. In this way, the signal utilized to determine the timing error is not provided through the memory device.

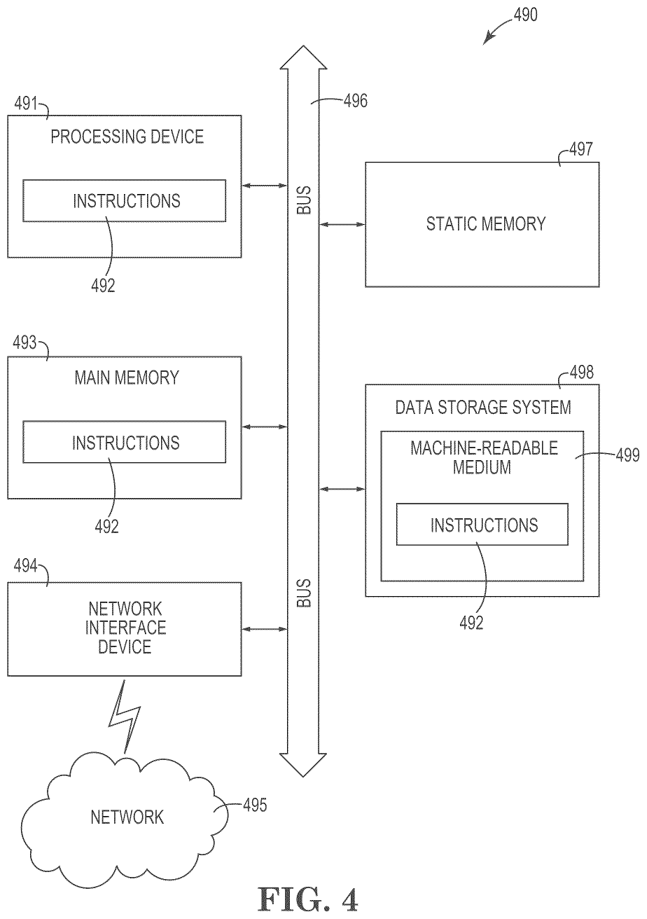

FIG. 4 is a block diagram of an example computer system 490 in which embodiments of the present disclosure may operate. For example, FIG. 4 illustrates an example machine of a computer system 490 within which a set of instructions, for causing the machine to perform any one or more of the methodologies discussed herein, can be executed. In some embodiments, the computer system 490 can correspond to a host system (e.g., the host 102 of FIG. 1) that includes, is coupled to, or utilizes a memory system (e.g., the system 221 of FIG. 2) or can be used to perform the operations of a controller (e.g., to execute an operating system to perform operations corresponding to the data path monitor 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 490 includes a processing device 491, a main memory 493 (e.g., read-only memory (ROM), flash memory, dynamic random access memory (DRAM) such as synchronous DRAM (SDRAM) or Rambus DRAM (RDRAM), etc.), a static memory 497 (e.g., flash memory, static random access memory (SRAM), etc.), and a data storage system 498, which communicate with each other via a bus 496.

The processing device 491 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 491 can also be one or more special-purpose processing devices such as an application specific integrated circuit (ASIC), a field programmable gate array (FPGA), a digital signal processor (DSP), network processor, or the like. The processing device 491 is configured to execute instructions 492 for performing the operations and steps discussed herein. The computer system 490 can further include a network interface device 494 to communicate over the network 495.

The data storage system 498 can include a machine-readable storage medium 499 (also known as a computer-readable medium) on which is stored one or more sets of instructions 492 or software embodying any one or more of the methodologies or functions described herein. The instructions 492 can also reside, completely or at least partially, within the main memory 493 and/or within the processing device 491 during execution thereof by the computer system 490, the main memory 493 and the processing device 491 also constituting machine-readable storage media. The machine-readable storage medium 499, data storage system 498, and/or main memory 493 can correspond to the system 221 of FIG. 2.

In one embodiment, the instructions 492 include instructions to implement functionality corresponding to syndrome calculation circuitry (e.g., the data path monitor 113 of FIG. 1). While the machine-readable storage medium 499 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. An apparatus, comprising:
a device having a data path associated therewith;
an error checking component coupled to the device and configured to receive data from the device via the data path; and
data path emulation circuitry configured to:
toggle between a first data set and a second data set to be provided to the error checking component from an emulated data path to monitor a property of the data path; and
determine whether to provide data to the error checking component from the data path or from the emulated data path based on an operational mode of the device.

2. The apparatus of claim 1, wherein the emulated data path includes one or more flip-flop circuits, one or more multiplexors, one or more delay circuits, and one or more gates to mimic a timing of the data path of the device.

3. The apparatus of claim 1, wherein the data path is a read data path when the device is a memory device and the property is one of a timing of the read data path or a data integrity of the emulated data path.

4. The apparatus of claim 1, wherein the operational mode is one of a read mode and a non-read mode.

5. The apparatus of claim 4, wherein the data path emulation circuitry is configured to provide data from the data path to the error checking component when the device is in the read mode and provide data from the emulated data path when the device is in the non-read mode.

6. The apparatus of claim 1, wherein the data path emulation is configured to generate a signal when a timing of the data provided to the error checking component from the emulated data path is outside a timing threshold.

7. The apparatus of claim 1, wherein the data path emulation circuitry is configured to switch a multiplexor to either provide data to the error checking component from the data path or provide toggled data from the emulated data path based on an operational mode of the device.

8. A method, comprising:
providing a clock signal to a device having a data path associated therewith, the data path being associated with providing data from the device to an error checking component;
providing the clock signal to data path emulation circuitry configured to monitor a timing of the data path by:
providing the clock signal to an emulated data path;
toggling between at least a first data set and a second data set; and
providing the toggled data to the error checking component based on the clock signal; and
determining whether to provide data to the error checking component from the data path or from the emulated data path based on an operational mode of the device.

9. The method of claim 8, further comprising preventing the clock signal from being provided to the emulated data path when the operation mode of the device is a read operational mode.

10. The method of claim 8, wherein the emulated data path is configured to provide the toggled data to the error checking component within a threshold timing associated with the data path of the device.

11. The method of claim 8, further comprising determining whether to provide data to the error checking component from the data path or from the emulated data path based on an operational mode of a data bus associated with the device.

12. The method of claim 11, wherein the operational mode of the data bus includes a data transfer operational mode and a non-operational mode.

13. The method of claim 8, further comprising determining when a detected error is associated with data from the data path or toggled data from the emulated data path.

14. The method of claim 8, further comprising determining an error is associated with the data path in response to determining a timing of the emulated data path is outside a timing threshold.

15. A system, comprising:
a device having a data path associated therewith;
an error checking component coupled to the device and configured to receive data from the device via the data path; and
data path emulation circuitry configured to:
determine an operational mode of the device;
provide a clock signal to an emulated data path in response to the operational mode of the device being a non-read operational mode;
toggle between a first data set and a second data set in response to the clock signal being provided to the emulated data path;
provide the toggled data to the error checking component from the emulated data path to monitor a timing of the data path; and
determine whether data provided to the error checking component is from the data path or from the emulated data path based on the operational mode of the device.

16. The system of claim 15, wherein the non-read operational mode is an operational mode where the device is not performing a read operation utilizing the data path.

17. The system of claim 15, wherein emulated data path includes delay circuitry to mimic a timing of the data path based on a propagation time and a margin time of the data path.

18. The system of claim 15, wherein the first data set is a first static data set and the second data set is a second static data set that is different from the first static data set.

19. The system of claim 15, wherein the error checking component is further configured to receive the toggled data from the emulated data path to determine a property of the emulated data path.

20. The system of claim 19, wherein the error checking component is further configured to compare the timing of the emulated data path to an expected timing and generate a timing violation when the timing of the emulated data path is outside a threshold of the expected timing.
